(19) United States
(12) Patent Application Publication
(10) Pub. No.: US 2018/0155830 A1
(43) Pub. Date: Jun. 7, 2018

(54) GAS SUPPLY AND EXHAUST STRUCTURE

(71) Applicant: TOKYO ELECTRON LIMITED, Tokyo (JP)

(72) Inventors: Ayuta SUZUKI, Yamanashi (JP); Kosuke Yamamoto, Yamanashi (JP); Kazuyoshi Matsuzaki, Yamanashi (JP); Munehito Kagaya, Yamanashi (JP); Tsuyoshi Moriya, Yamanashi (JP); Tadashi Mitsunari, Yamanashi (JP)

(21) Appl. No.: 15/833,889

(22) Filed: Dec. 6, 2017

(30) Foreign Application Priority Data
Dec. 7, 2016 (JP) 2016-237821

(51) Int. Cl. C23C 16/44; C23C 16/455

(52) U.S. Cl. CPC C23C 16/4412; C23C 16/45561

(57) ABSTRACT

A gas supply and exhaust structure, for supplying and exhausting a raw material gas into and from a chamber having a substrate mounting surface at a position corresponding to a central portion of an inner top surface, includes a side gas supply unit having gas supply ports arranged circumferentially and vertically on an inner side surface of the chamber and configured to supply the raw material gas through the gas supply ports toward a central axis of the chamber, and an exhaust unit having a gas exhaust port formed at the central portion of the inner top surface of the chamber and configured to exhaust the raw material gas. The inner top surface has an inclined surface inclined such that a distance between the inner top surface and an inner bottom surface of the chamber becomes smaller from the inner side surface toward the central axis.

### CROSS-REFERENCE TO RELATED APPLICATIONS

This application claims priority to Japanese Patent Application No. 2016-237821 filed on Dec. 7, 2016, the entire contents of which are incorporated herein by reference.

### FIELD OF THE INVENTION

The disclosure relates to a gas supply and exhaust structure.

### BACKGROUND OF THE INVENTION

Film forming methods are disclosed in U.S. Pat. No. 8,282,735 (Reference 1), Japanese Patent Application Publication No. 2002-118104 (Reference 2), Japanese Patent Application Publication No. 2009-224441 (Reference 3) and Japanese Patent Application Publication No. 2014-7087 (Reference 4). In the film forming method disclosed in Reference 1, a raw material gas for film formation is supplied toward a substrate through a gas supply port provided at a side portion of a processing space where a substrate (wafer) is accommodated and exhausted from a position located diagonally with respect to the gas supply port. Accordingly, the raw material gas flows along one direction on a top surface of the substrate. In the film forming method disclosed in Reference 2, a raw material gas for film formation is supplied toward a substrate provided at the center in a processing space from a circumferential side of the processing space and exhausted from an exhaust port installed at a lower portion of the processing space. In the film forming method disclosed in Reference 3, a shower head is provided at an upper portion of a processing space where a substrate is accommodated; a gas supply port is provided at a central portion and a peripheral portion of the shower head; and a plurality of exhaust holes is formed between the gas supply port formed at the central portion and the gas supply port formed at the peripheral portion. In the film forming method disclosed in Reference 4, an exhaust port is provided at an upper central portion of a processing space and a gas supply port is formed concentrically around the exhaust port.

In a gas supply method disclosed in Reference 1, the raw material gas flows along one direction on the surface of the substrate and, thus, the concentration of the raw material at a downstream side is lower than the concentration of the raw material at an upstream side. In other words, when the gas is supplied in one direction, the film thickness may be gradually decreased in one direction along the flow direction of the raw material gas. Gas supply methods disclosed in References 2 to 4 are effective in controlling in-plane uniformity of a film thickness, processing uniformity and pressure distribution but insufficient in controlling concentration distribution of the raw material supplied onto the substrate.

### SUMMARY OF THE INVENTION

In accordance with an aspect, there is provided a gas supply and exhaust structure for supplying and exhausting a raw material gas into and from a chamber having a substrate mounting surface at a position corresponding to a central portion of an inner top surface. The gas supply and exhaust structure includes a side gas supply unit and an exhaust unit. The side gas supply unit has a plurality of gas supply ports arranged in a circumferential direction and in a vertical direction on an inner side surface of the chamber and is configured to supply the raw material gas through the gas supply ports toward a central axis of the chamber. The exhaust unit has a gas exhaust port formed at the central portion of the inner top surface of the chamber and configured to exhaust the raw material gas. The inner top surface has an inclined surface which is inclined such that a distance between the inner top surface and an inner bottom surface of the chamber becomes smaller from the inner side surface toward the central axis.

### BRIEF DESCRIPTION OF THE DRAWINGS

The objects and features of the disclosure will become apparent from the following description of embodiments, given in conjunction with the accompanying drawings, in which:

FIG. 1 schematically shows a film forming apparatus according to an embodiment;

FIG. 2 is a view for explaining installation positions of first gas supply ports in a processing space;

FIG. 3 shows an inner top surface of a chamber which is seen from the bottom;

FIG. 4 explains a side gas supply unit of a gas supply and exhaust structure according to a modification;

FIGS. 5A to 5D show gas supply and exhaust structures subjected to simulations of gas concentration distribution; and

FIGS. 6A and 6B shows results of the simulations of the gas concentration distribution of the gas supply and exhaust structures shown in FIG. 5.

### DETAILED DESCRIPTION OF THE EMBODIMENTS

Hereinafter, embodiments will be described in detail with reference to the accompanying drawings. Like reference numerals will be given to like or corresponding parts throughout the drawings.

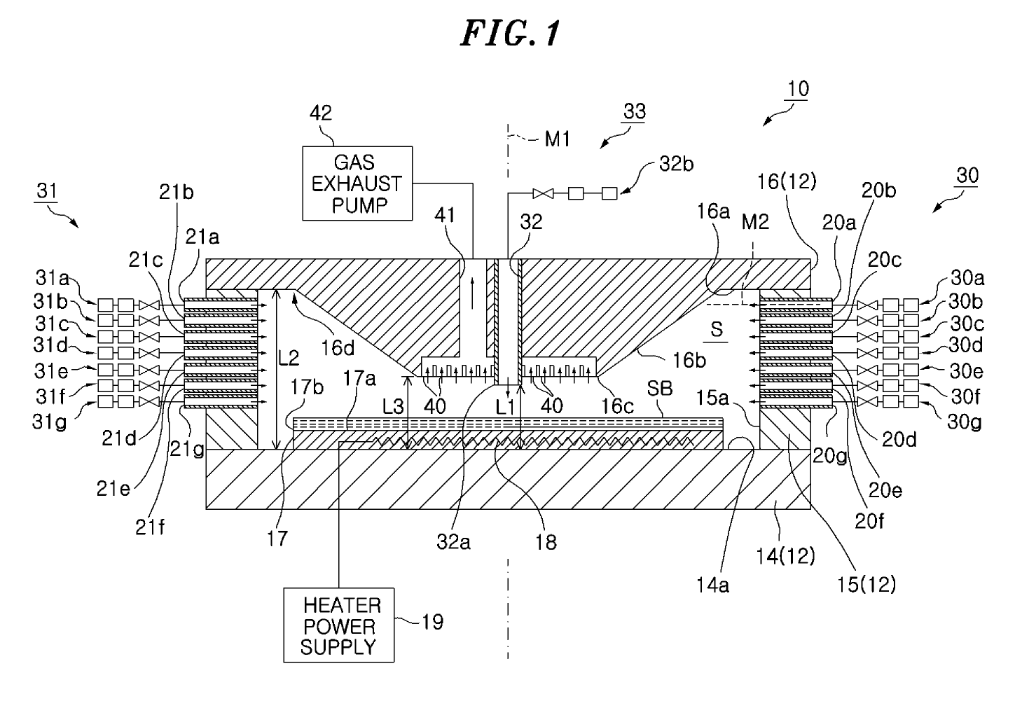

FIG. 1 schematically shows a film forming apparatus according to an embodiment. A film forming apparatus 10 shown in FIG. 1 includes a chamber main body 12. The chamber main body 12 includes a bottom portion 14, a side portion 15 and a ceiling portion 16. A processing space S is provided in the chamber main body 12. The bottom portion 14 has a substantially circular inner bottom surface 14a that is a bottom surface of the processing space S. The side portion 15 is dispose on the bottom portion 14. The side portion 15 has an inner side surface 15a that is a side surface of the processing space S. The side portion 15 has a substantially cylindrical shape. The central axis of the side portion 15 substantially coincides with an axis line Ml extending in a vertical direction. The side portion 15 may be made of a metal, e.g., aluminum. A corrosion resistant film may be formed on the inner side surface 15a. The ceiling portion 16 is disposed on the side portion 15. The ceiling portion 16 has a substantially circular inner top surface that is a top surface of the processing space S.

The inner top surface of the chamber main body 12 includes, e.g., an upper edge portion 16a, an inclined surface 16b and a central portion 16c. The central portion 16c is formed at a position through which the axis line Ml extends, e.g., at a position inner than a position corresponding to a half of a radius of the inner top surface. The central portion 16c projects downward. A distance L3 between the central portion 16c and the inner bottom surface 14a is smaller than a distance L2 between the upper edge portion 16a and the inner bottom surface 14a. In other words, the inclined surface 16b is inclined such that the distance between the inner top surface and the inner bottom surface 14a becomes smaller toward the axis line Ml from the inner side surface 15a. For example, the inclined surface 16b is inclined smoothly (continuously).

A stage 17 is provided in the chamber main body 12. The stage 17 has a substantially disc shape. A top surface of the stage 17 serves as a substrate mounting surface 17a. The substrate mounting surface 17a is a predetermined surface for mounting thereon a substrate SB. For example, the substrate mounting surface 17a is brought into contact with a backside of the substrate SB and has substantially the same area as that of the backside of the substrate SB. The substrate mounting surface 17a may be physically defined by an end portion of the stage 17 or an inner side of the focus ring. When the mounting position of the substrate SB is predetermined, the physical boundary may not be provided. For example, when the stage 17 is not provided, a predetermined region on the inner bottom surface of the chamber main body serves as the substrate mounting surface 17a.

The substrate SB is mounted on the substrate mounting surface 17a. A heater 18 is provided in the stage 17. The heater 18 is electrically connected to a heater power supply 19. The heater power supply 19 is installed at the outside of the chamber main body 12.

The substrate mounting surface 17a is provided at a position corresponding to the central portion 16c of the inner top surface of the chamber main body 12. The inclined surface 16b of the inner top surface of the chamber main body 12 is inclined from a position 16d corresponding to an end 17b of the substrate mounting surface 17a to the central portion 16c (gas exhaust ports 40 to be described later), for example. In other words, the inclined surface 16b is inclined from an outer side of the position corresponding to the end of the substrate SB to the central portion 16c. The inclination of the inclined surface 16b may be appropriately set. For example, the distance L2 from the end portion of the substrate mounting surface 17a to the inner top surface may be set to be greater, by twice or more, than the distance L3 from the substrate mounting surface 17a to the central portion 16c (the gas exhaust ports 40 to be described later).

The film forming apparatus 10 includes side gas supply units for supplying a gas from a circumferential side of the substrate mounting surface 17a. FIG. 1 illustrates only side gas supply units 30 and 31 arranged diagonally. The side gas supply units 30 and 31 include a plurality of first gas supply ports 20a to 20g and 21a to 21g arranged in a vertical direction at the inner side surface 15a, respectively. The side gas supply units 30 and 31 supply gases through the first gas supply ports toward the axis line M1 of the chamber main body 12.

Gas supply mechanisms 30a to 30g are connected to the first gas supply ports 20a to 20g, respectively. Gas supply mechanisms 31a to 31g are connected to the first gas supply ports 21a to 21g, respectively. Each of the gas supply mechanisms includes a gas source, a flow rate controller and a valve. As for the gas source, there may be employed a gas source of a raw material gas, a gas source of an activation gas, a gas source of a carrier gas and the like. The flow rate controller is a mass flow controller or a pressure control type flow rate controller. The valve is an electromagnetic valve or the like. The gas supply mechanisms may supply various gases at preset flow rates through the first gas supply ports 20a to 20g and 21a to 21g.

At least one of the first gas supply ports 20a to 20g and 21a to 21g is configured to supply a gas toward the inclined surface 16b. For example, the gas is supplied through the first gas supply port 20a in a gas supply direction M2 to reach the inclined surface 16b. Similarly, the gases supplied from the first gas supply ports 20b to 20e and 21a to 21e are supplied toward the inclined surface 16b.

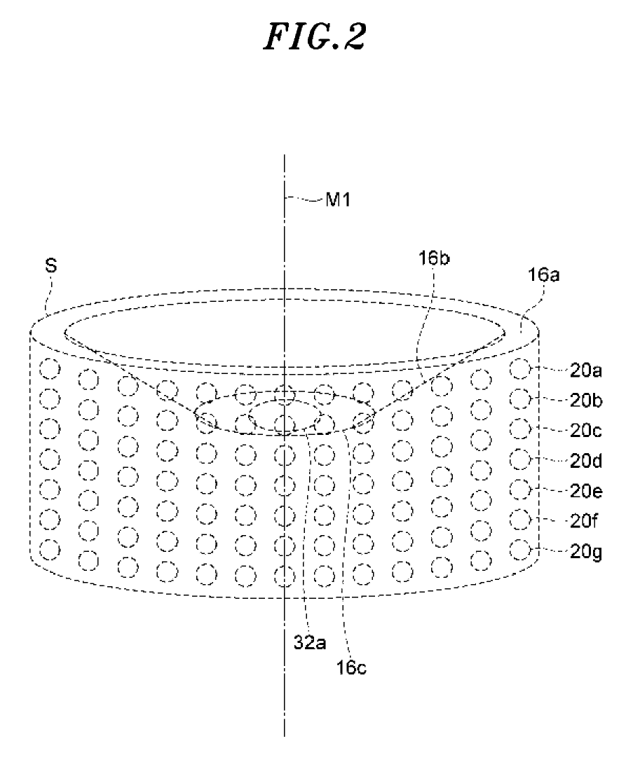

FIG. 2 explains installation positions of the first gas supply ports in the processing space S. As shown in FIG. 2, the first gas supply ports 20a to 20g are also arranged on the side surface of the processing space S along the circumferential direction. The circumferentially arranged first gas supply ports 20a to 20g are also connected to the respective gas supply mechanisms. The outlets of the first gas supply ports have a circular shape. When the outlets are formed in a circular shape, gas jet flow becomes stable.

The film forming apparatus 10 includes, e.g., a central gas supply unit 33 for supplying a gas from above the substrate mounting surface 17a. The central gas supply unit 33 includes a second gas supply port 32 and a gas supply mechanism 32b. The second gas supply port 32 extends through the ceiling portion 16 of the chamber main body 12. For example, the second gas supply port 32 is formed along the axis line M1 of the chamber main body 12. A lower end 32a of the second gas supply port 32 protrudes below the inner top surface (the central portion 16c). In other words, a distance L1 from the lower end 32a of the second gas supply port 32 to the inner bottom surface 14a is smaller than the distance L3 from the central portion 16c to the inner bottom surface 14a. The gas supply mechanism 32b includes a gas source, a flow rate controller and a valve. The gas supply mechanism 32b can supply a gas at a predetermined flow rate. As for the gas source, there may be employed a source gas of a raw material gas, a source gas of an activation gas, a source gas of a carrier gas and the like.

The film forming apparatus 10 includes a gas exhaust unit for exhausting a gas from a portion above the substrate mounting surface 17a. The gas exhaust unit includes gas exhaust ports 40, a gas exhaust path 41 and a gas exhaust pump 42. The gas exhaust ports 40 are formed at the central portion 16c of the inner top surface of the chamber main body 12. In the example shown in FIG. 1, a plurality of gas exhaust ports 40 is formed at the central portion 16c.

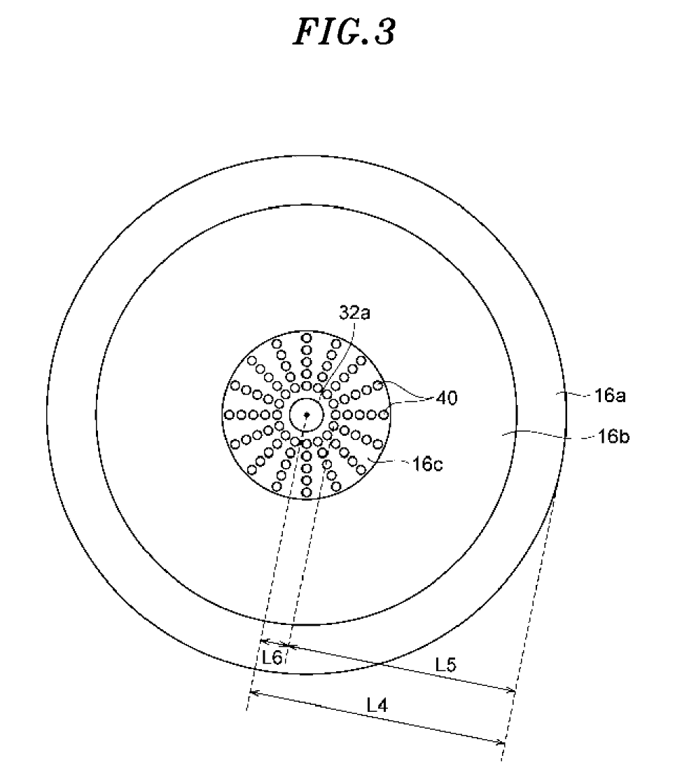

FIG. 3 shows the inner top surface of the chamber main body 12 which is seen from the bottom. As shown in FIG. 3, the gas exhaust ports 40 are formed at the central portion 16c and arranged to surround the second gas supply port 32. In other words, a distance L4 from the second gas supply port 32 to the inner side surface 15a is longer than a distance L5 from the gas exhaust ports 40 to the inner side surface 15a. A distance L6 from the gas exhaust ports 40 to the axis line Ml is smaller than the distance L5 from the gas exhaust ports 40 to the inner side surface 15a. In other words, the gas exhaust ports 40 are formed at positions inner than a position corresponding to a half of a radius of the inner top surface. The gas exhaust ports 40 formed at the central portion 16c are located at positions where the above relations are satisfied.

Referring back to FIG. 1, the gas exhaust ports 40 communicate with the gas exhaust path 41. The gas exhaust path 41 is connected to the gas exhaust pump 42. The raw material gas is exhausted from a portion above the substrate SB through the gas exhaust ports 40 and the gas exhaust path 41.

Next, an example of processes in the film forming apparatus 10 will be described. The side gas supply unit generates jet flow from lateral side toward the center of the processing space S. Thus, the carrier gas is constantly supplied through the first gas supply ports during the film formation. The side gas supply unit and the central gas supply unit supply the raw material gas, carried by the carrier gas, through a certain gas supply port (a part or all of the first gas supply ports and/or the second gas supply port). Accordingly, the raw material gas is adsorbed onto a desired position on the top surface of the substrate SB.

Next, the side gas supply unit and the central gas supply unit supply the activation gas, carried by the carrier gas, through a certain gas supply port (a part or all of the first gas supply ports and/or the second gas supply port). Accordingly, the activation gas is supplied to a desired portion on the top surface of the substrate SB. The adsorbed raw material gas and the activation gas react with each other, thereby forming a monomolecular layer.

The side gas supply unit and the central gas supply unit form a film having a desired film thickness by repeatedly supplying the raw material gas and the activation gas. A ratio of gases supplied by the side gas supply unit and the central gas supply unit may be changed to realize uniform film formation or non-uniform film formation which is thicker in center or edge.

In the gas supply and exhaust structure of the present embodiment, the raw material gas is supplied through the first gas supply ports 20a to 20g and 21a to 21g arranged in a vertical direction and in a circumferential direction toward the axis line M1 of the chamber main body 12. The raw material gas is supplied lateral side to the substrate SB mounted on the substrate mounting surface 17a and exhausted through the gas exhaust ports 40 positioned above the central portion of the substrate mounting surface 17a. Thus, the concentration distribution of the raw material is controlled such that the concentration is gradually increased from the center to the edge of the substrate mounting surface 17a.

The raw material gas supplied through the first gas supply ports 20a to 20e and 21a to 21e becomes in contact with the inclined surface 16b of the inner top surface of the chamber main body 12 and flows along the inclined surface 16b. The inclined surface 16b is inclined such that the distance between the inner top surface and the inner bottom surface 14a becomes smaller from the inner side surface 15a toward the axis line M1. Accordingly, the raw material gas can be supplied toward the center of the substrate mounting surface 17a where it is difficulat for the raw material gas to reach. For example, as the inclination of the inclined surface 16b is increased, the concentration of the raw material gas supplied to the center of the substrate is increased. In other words, the concentration distribution of the raw material supplied to the substrate SB can be controlled such that it becomes higher at the edge portion or becomes uniform over the entire surface by combining the configuration in which the raw material gas is supplied from the circumferential side of the chamber main body 12 and exhausted from the portion above the central portion and the configuration in which the inner top surface of the chamber main body 12 has the inclined surface 16b. For example, by controlling the flow rate of the gas supplied toward the inclined surface 16b, the raw material concentration can become higher at the edge portion of the substrate SB than at the central portion of the substrate SB or can become uniform over the entire surface of the substrate SB. This gas supply and exhaust structure enables the concentration distribution of the raw material supplied onto the substrate SB to be controlled.

In the gas supply and exhaust structure of the present embodiment, the inclined surface 16b is inclined from the position 16d corresponding to the end 17b of the substrate mounting surface 17a to the gas exhaust ports 40 and, thus, the substrate SB and the inclined surface 16b can be made to face each other. Since the inclined surface 16b is positioned above the substrate mounting surface 17a, the raw material gas can be supplied toward the center of the substrate mounting surface 17a.

In the gas supply and exhaust structure of the present embodiment, the first gas supply ports 20a to 20e and 21a to 21e, among the first gas supply ports 20a to 20g and 21a to 21g, are arranged to supply the raw material gas toward the inclined surface 16b and, thus, the raw material gas can flow along the inclined surface 16b while being in contact with the inclined surface 16b. Accordingly, the raw material gas can be supplied toward the central portion of the substrate mounting surface 17a where it is difficult for the raw material gas to reach.

The gas supply and exhaust structure of the present embodiment includes the central gas supply unit 33 and thus can supply the raw material gas toward the central portion of the substrate mounting surface 17a where it is difficult for the raw material gas supplied from the lateral side to reach. With this configuration, the concentration distribution of the raw material supplied onto the substrate SB can be controlled such that it becomes higher at the central portion.

In the gas supply and exhaust structure of the present embodiment, the gas exhaust ports 40 are formed around the second gas supply port 32. Therefore, the raw material gas can be easily supplied to the central portion of the substrate SB compared to when the second gas supply port 32 is provided around the gas exhaust ports 40. In that case, a decrease in the concentration distribution at the central portion by the exhaust operation can be reduced compared to when the gas exhaust ports 40 are located at the central portion.

In the gas supply and exhaust structure of the present embodiment, the lower end of the second gas supply port projects below the inner top surface and, thus, it is possible to prevent the raw material gas supplied through the second gas supply port 32 from being exhausted before it reaches the central portion of the substrate SB.

While the embodiments have been described, the gas supply and exhaust structure of the present disclosure is not limited to the above embodiments and may be variously modified.

### Modification

In the above embodiments, the film forming apparatus 10 using heat treatment has been described. However, the film forming apparatus of the present disclosure may be a plasma processing apparatus. In that case, any of a lower-side application type and an upper-side application type may be employed and an electrostatic chuck may be installed at the stage 17. The inner top surface may not have the upper edge portion 16a and may have only the inclined surface 16b and the central portion 16c. In that case, the inclined surface 16b is continuously inclined from the inner side surface 15a to the gas exhaust ports 40. When the width of the upper edge portion 16a is at least 10 mm, the gas can stably flow toward the end portion of the substrate.

The inclined surface 16b may be formed in a stepped shape. When the inclined surface 16b is smoothly inclined as described above, a part of the raw material gas flows along the inclined surface 16b and, thus, the concentration distribution of the raw material supplied onto the substrate become more uniform compared to when the inclined surface 15b is inclined in a stepped shape.

The central portion 16c is not necessarily flat and may be inclined toward the center. The central gas supply unit 33 is not essential and may be provided if necessary.

A plurality of gas supply mechanisms may not necessarily provided and at least on gas supply mechanism (at least one first gas supply port) may be provided.

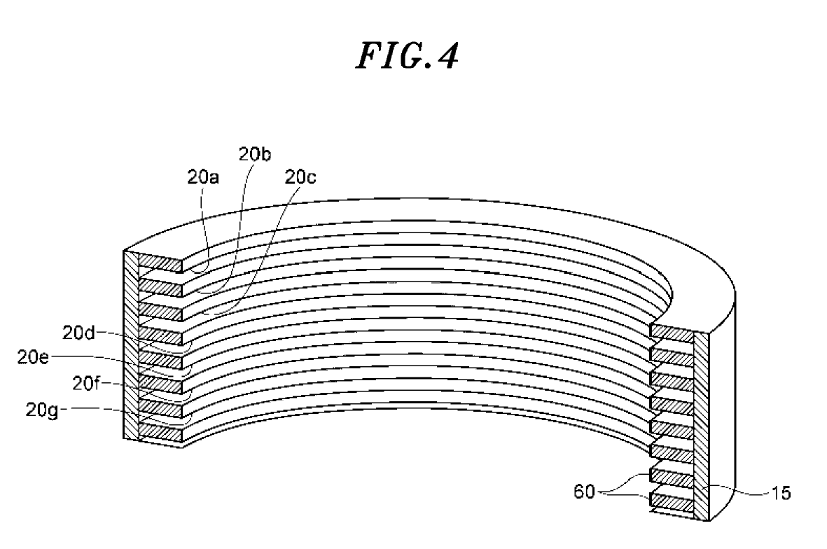

The shape of the outlets of the first gas supply ports is not limited to a circular shape. For example, the outlets of the first gas supply ports may have a slit shape. FIG. 4 explains a side gas supply unit of the gas supply and exhaust structure according to a modification. As shown in FIG. 4, the outlets of the first gas supply ports 20a to 20g of the side gas supply unit are formed as slits along the entire circumferential direction and arranged in a vertical direction. When the outlets of the first gas supply ports are formed as slits, the gas can be supplied symmetrically in the circumferential direction. The outlets of the first gas supply ports may have a quadrilateral shape. For example, when it is difficult in terms of the apparatus configuration to form the outlets of the first gas supply ports as slits along the entire circumferential direction, a shape similar to the slit shape can be obtained by forming a circumferentially enlogated outlets along the circumferential direction.

The film forming apparatus 10 may not have the stage 17. In that case, a predetermined region on the inner bottom surface of the chamber main body 12 serves as the substrate mounting surface 17a.

### Test Examples

Hereinafter, test examples performed by the present inventors will be described.

### Controllability of Inclined Surface on Concentration Distribution

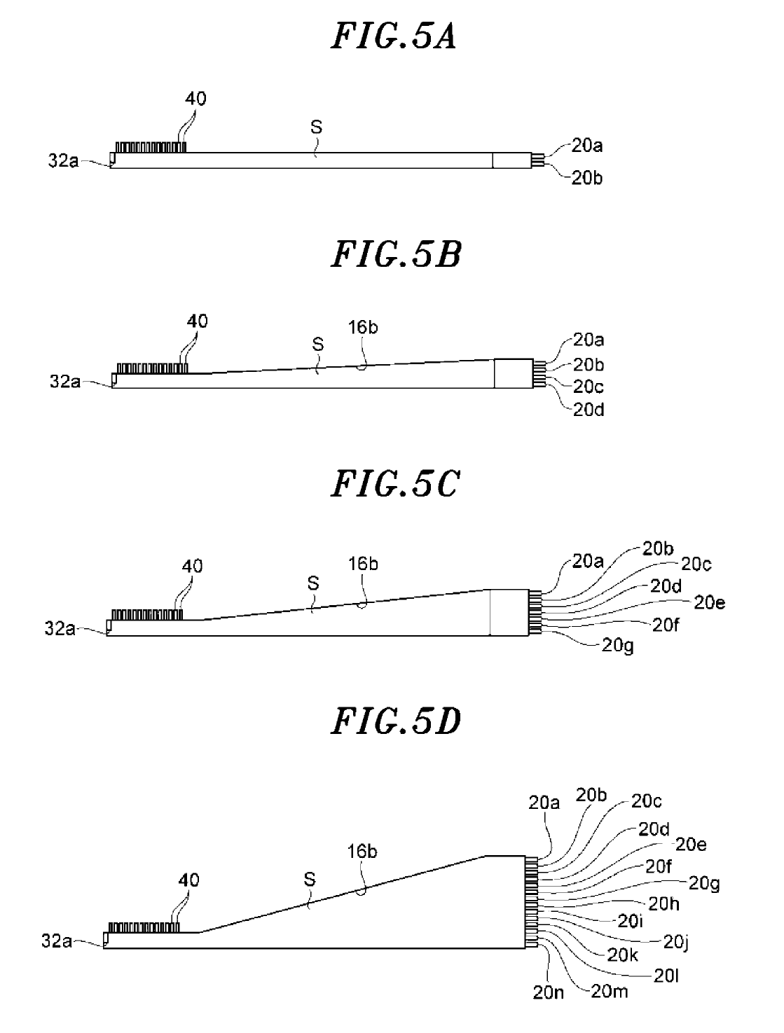

Simulations were performed to check whether or not the concentration distribution was controllable by the inclined surface 16b. FIGS. 5A to 5D show gas supply and exhaust structures subjected to simulations of gas concentration distribution. The gas supply and exhaust structure shown in FIG. 5A has a flat inner top surface and has no inclined surface. A distance from an upper edge portion of the inner top surface to an inner bottom surface was 6 mm. A distance from a central portion of the inner top surface to the inner bottom surface was 6 mm. The first gas supply ports 20a and 20b were arranged in two vertical rows and along a circumferential direction at a side portion. A first gas was supplied through the upper first gas supply port 20a and a carrier gas was supplied through the lower first gas supply port 20b. The carrier gas was supplied constantly to generate jet flow. The first gas was carried by the carrier gas and supplied. The concentration distribution of the first gas on a substrate having a radius of 155 mm was simulated.

The gas supply and exhaust structure shown in FIG. 5B has an inclined surface 16b on an inner top surface. A distance from an upper edge portion of the inner top surface to an inner bottom surface was 12 mm. A distance from a central portion of the inner top surface to the inner bottom surface was 6 mm. The first gas supply ports 20a to 20d were arranged in four vertical rows and along a circumferential direction at a side portion. A first gas was supplied through the uppermost first gas supply port 20a. A carrier gas was supplied through the other first gas supply ports 20b to 20d. The carrier gas was constantly supplied to generate jet flow. The first gas was carried by the carrier gas and supplied. The concentration distribution of the first gas on a substrate having a radius of 155 mm was simulated.

A gas supply and exhaust structure shown in FIG. 5C has an inclined surface 16b on an inner top surface. A distance from an upper edge portion of the inner top surface to an inner bottom surface was 18 mm. A distance from a central portion of the inner top surface to the inner bottom surface was 6 mm. The first gas supply ports 20a to 20g were arranged in seven vertical rows and along a circumferential direction at a side portion. A first gas was supplied through the uppermost first gas supply port 20a. A carrier gas was supplied through the other first gas supply ports 20b to 20g. The carrier gas was constantly supplied to generate jet flow. The first gas was carried by the carrier gas and supplied. The concentration distribution of the first gas on a substrate having a radius of 155 mm was simulated.

A gas supply and exhaust structure shown in FIG. 5D has an inclined surface 16b on an inner top surface. A distance from an upper edge portion of the inner top surface to an inner bottom surface was 36 mm. A distance from a central portion of the inner top surface to the inner bottom surface was 6 mm. The first gas supply ports 20a to 20n were arranged in forteen vertical rows and along a circumferential direction at a side portion. A first gas was supplied through the uppermost first gas supply port 20a. A carrier gas was supplied through the other first gas supply ports 20b to 20n. The carrier gas was constantly supplied to generate jet flow. The first gas was carried by the carrier gas and supplied. The concentration distribution of the first gas on a substrate having a radius of 155 mm was simulated.

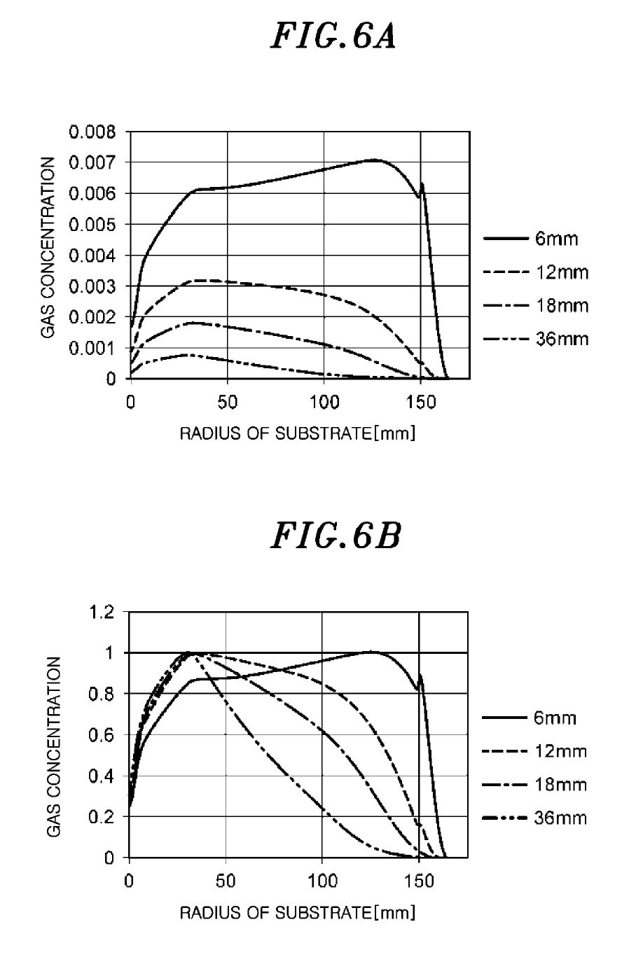

FIGS. 6A and 6B show results of the simulations of the gas concentration distribution. In the graph of FIG. 6A, the horizontal axis represents a radius of a substrate and the vertical axis represents a gas concentration. The gas concentration indicates a concentration of the first gas contained in the entire gas including the carrier gas. As can be seen from the graph of FIG. 6A, when the distance from the upper edge portion of the inner top surface to the inner bottom surface is 6 mm, the peak of the gas concentration appears at a position where the radius of the substrate is about 125 mm. On the other hand, when the distance from the upper edge portion of the inner top surface to the inner bottom surface is within a range from 12 mm to 36 mm, the peak of the gas concentration appears at a position where the radius of the substrate is within a range from about 25 mm to 30 mm. The graph of FIG. 6B is obtained by normalizing a maximum value of the gas concentration in the graph of FIG. 6A to 1. As can be seen from FIGS. 6A and 6B, it has been confirmed that when the distance from an outer periphery of the inner top surface to the inner bottom surface is greater, by twice or more, than the distance from the central portion of the inner top surface to the inner bottom surface (12 mm to 36 mm in FIGS. 6A and 6B), the peak of the gas concentration can appear at the central portion of the substrate. In addition, it has been confirmed that the concentration of the raw material supplied to the central portion of the substrate can be increased as the inclination of the inclined surface 16b is increased. In other words, the concentration distribution can be controlled by the inclined surface 16b.

While the disclosure has been shown and described with respect to the embodiments, it will be understood by those skilled in the art that various changes and modifications may be made without departing from the scope of the disclosure as defined in the following claims.

What is claimed is:

1. A gas supply and exhaust structure for supplying and exhausting a raw material gas into and from a chamber having a substrate mounting surface at a position corresponding to a central portion of an inner top surface, the structure comprising:
a side gas supply unit having a plurality of first gas supply ports arranged in a circumferential direction and in a vertical direction on an inner side surface of the chamber and configured to supply the raw material gas through the gas first supply ports toward a central axis of the chamber; and
an exhaust unit having a gas exhaust port formed at the central portion of the inner top surface of the chamber and configured to exhaust the raw material gas,
wherein the inner top surface has an inclined surface which is inclined such that a distance between the inner top surface and an inner bottom surface of the chamber becomes smaller from the inner side surface toward the central axis.

2. The gas supply and exhaust structure of claim 1, wherein a distance from the exhaust port to the central axis is smaller than a distance from the exhaust port to the inner side surface.

3. The gas supply and exhaust structure of claim 1, wherein the inclined surface is inclined from a position corresponding to an end of the substrate mounting surface to the exhaust port.

4. The gas supply and exhaust structure of claim 1, wherein a distance from an end portion of the substrate mounting surface to the inner top surface is greater, by twice or more, than a distance from the substrate mounting surface to the exhaust port.

5. The gas supply and exhaust structure of claim 1, wherein at least one of the first gas supply ports is configured to supply the raw material gas toward the inclined surface.

6. The gas supply and exhaust structure of claim 1, further comprising:
a central gas supply unit including a second gas supply port which is formed along the central axis of the central portion of the inner top surface, and configured to supply the raw material gas through the second gas supply port toward the substrate mounting surface.

7. The gas supply and exhaust structure of claim 6, wherein the gas exhaust port is formed around the second gas supply port.

8. The gas supply and exhaust structure of claim 6, wherein a lower end of the second gas supply port projects below the inner top surface.
